(19) United States
(12) Patent Application Publication
(10) Pub. No.: US 2026/0344028 A1
(43) Pub. Date: Oct. 29, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Sheng-Yuan Hsueh, Tainan City (TW); Chun-Hsien Lin, Tainan City (TW); Wen-Kai Lin, Yilan County (TW); Yu-Hsuan Lin, New Taipei City (TW); Chih-Kai Kang, Tainan City (TW); Yung-Chen Chiu, Taichung City (TW); Ting-Hsiang Huang, Tainan City (TW); Sheng-Ting Hong, Taichung City (TW); Yao-Jhan Wang, Tainan City (TW)

(73) Assignee: UNITED MICROELECTRONICS CORP., Hsin-Chu City (TW)

(21) Appl. No.: 19/215,279

(22) Filed: May 21, 2025

(30) Foreign Application Priority Data
Apr. 23, 2025 (TW) 114115288

(51) Int. Cl. H10D 84/83; H10D 30/01; H10D 30/62; H10D 64/01; H10D 64/66; H10D 84/01

(52) U.S. Cl. CPC H10D 84/834; H10D 30/024; H10D 30/6211; H10D 64/015; H10D 64/021; H10D 64/675; H10D 84/0147; H10D 84/0158

(57) ABSTRACT

A method for fabricating a semiconductor device includes the steps of first providing a substrate having a core region and an input/output (I/O) region, forming a first gate structure on the core region and a second gate structure on the I/O region, forming a first spacer adjacent to the first gate structure and a second spacer adjacent to the second gate structure, and then forming a first source/drain region adjacent to the first spacer and a second source/drain region adjacent to the second spacer. Preferably, the first spacer and the second spacer have different widths.

### BACKGROUND OF THE INVENTION

### 1. Field of the Invention

The invention relates to a method for fabricating semiconductor device, and more particularly, to a method of forming spacers with different thickness on core region and input/output (I/O) region.

### 2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in the current manufacturing processes of metal gate transistors, particularly in the input/output (I/O) regions and core regions, the preset gate dielectric layer thickness often results in suboptimal electrical performance. Therefore, how to improve the existing metal gate fabrication process to address this issue has become an important challenge in the industry.

### SUMMARY OF THE INVENTION

According to an embodiment of the present invention, a method for fabricating a semiconductor device includes the steps of first providing a substrate having a core region and an input/output (I/O) region, forming a first gate structure on the core region and a second gate structure on the I/O region, forming a first spacer adjacent to the first gate structure and a second spacer adjacent to the second gate structure, and then forming a first source/drain region adjacent to the first spacer and a second source/drain region adjacent to the second spacer. Preferably, the first spacer and the second spacer have different widths.

According to another aspect of the present invention, a semiconductor device includes a substrate having a core region and an input/output (I/O) region, a first gate structure in the core region and a second gate structure in the I/O region, a first spacer adjacent to the first gate structure and a second spacer adjacent to the second gate structure, and a first source/drain region adjacent to the first spacer and a second source/drain region adjacent to the second spacer. Preferably, the first spacer and the second spacer have different widths.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

FIGS. 8-10 illustrate a method for fabricating a semiconductor device according to an embodiment of the present invention.

### DETAILED DESCRIPTION

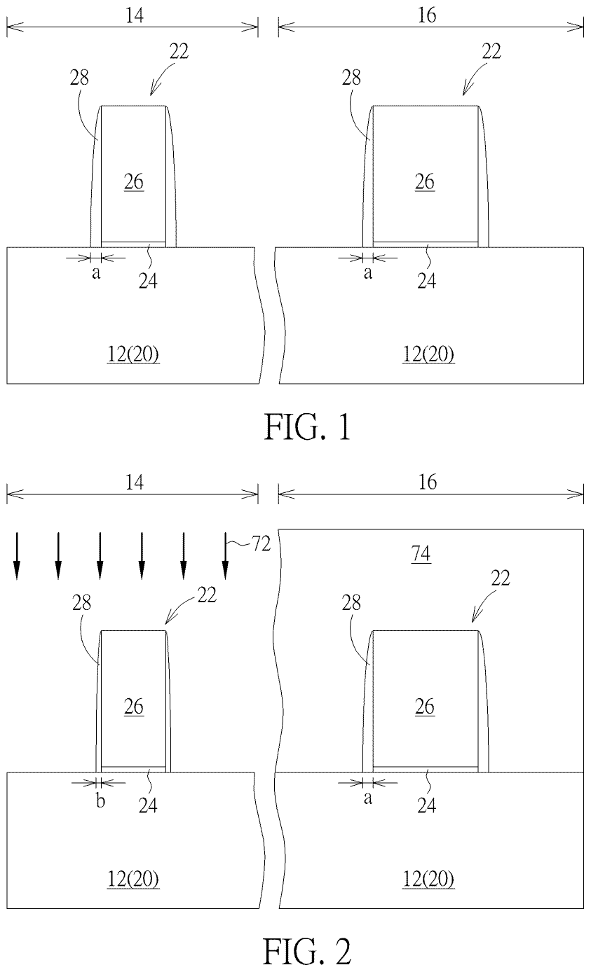

Referring to FIGS. 1-7, FIGS. 1-7 illustrate a method for fabricating a semiconductor device according to one embodiment of the present invention. As shown in FIG. 1, a substrate is first provided, for example, a silicon substrate or a silicon-on-insulator (SOI) substrate. A core region 14 and an input/output (I/O) region 16 are defined on the substrate 12. In this embodiment, it is preferable that the core region 14 and the I/O region 16 are both transistor regions of the same conductivity type, such as both being PMOS regions or both being NMOS transistor regions.

Each of the core region 14 and the I/O region 16 on the substrate 12 includes at least one fin-shaped structure 20 and the bottom portion of the fin-shaped structure 20 is surrounded by an insulating material, such as silicon dioxide, to form shallow trench isolation (STI) (not shown in the figure). It should be noted that although the present embodiment uses a non-planar fin-type field-effect transistor (FinFET) as an example, the invention is not limited thereto. The present invention is also applicable to planar field-effect transistors, which are likewise encompassed within the scope of this embodiment.

According to an embodiment of the present invention, the fin-shaped structure 20 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 20 could also be obtained by first forming a patterned mask (not shown) on the substrate, 12, and through an etching process, the pattern of the patterned mask is transferred to the substrate 12 to form the fin-shaped structure 20. Moreover, the formation of the fin-shaped structure 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 20. These approaches for forming fin-shaped structure 20 are all within the scope of the present invention.

Next, gate structures 22 or dummy gates are formed on the core region 14 and I/O region 16 of the substrate 12. In this embodiment, the formation of the gate structures 22 could be accomplished by sequentially depositing a gate dielectric layer 24, a gate material layer 26, and a selective hard mask (not shown) on the substrate 12, conducting a pattern transfer process by using a patterned resist (not shown) as mask to remove part of the gate material layer 26 and part of the gate dielectric layer 24, and then stripping the patterned resist to form gate structures 22 on the fin-shaped structure 20 on the core region 14 and I/O region 16. Each of the gate structures 22 preferably includes a patterned gate dielectric layer 24 and a patterned material layer 26, in which the gate dielectric layer 24 includes silicon oxide and the gate material layer 26 includes polysilicon, but not limited thereto.

Subsequently, at least one spacer 28, such as an offset spacer, is formed on the sidewalls of each gate structure 22. At this stage, the spacers 28 formed in both the core region 14 and the I/O region 16 have the same thickness or width ‘a’. Preferably, the width ‘a’ of each spacer 28 is greater than 20 Angstroms, for example, ranging between 20 and 25 Angstroms. The spacers 28 are preferably composed of dielectric materials or compounds that do not contain oxygen, such as, but not limited to, silicon nitride (SiN) or silicon carbide (SiC). In the present embodiment, the thickness of the spacer 28 could be defined as the maximum width of the spacer 28 extending in the horizontal direction or the X-direction.

Next, as shown in FIG. 2, a treatment process 72 is performed to remove a portion of the spacers 28 in the core region 14, while leaving the spacers 28 in the I/O region 16 unaffected. More specifically, a patterned mask 74, such as a patterned resist is first formed over the I/O region 16. Then, using the patterned mask 74 as a mask, the treatment process 72 such as a wet etching or dry etching process is carried out to remove part of the spacers 28 in the core region 14, thereby reducing the spacer width ‘a’to a narrower width ‘b’.

Since the spacers 28 in the I/O region 16 are shielded by the patterned mask 74 during the etching process, they remain unaffected. As a result, after the treatment process 72, the width ‘b’ of the spacers 28 in the core region 14 is preferably slightly smaller than the width ‘a’ of the spacers 28 in the I/O region 16. According to one embodiment of the present invention, after thinning by the treatment process 72, the width ‘b’ of the spacers 28 in the core region 14 is preferably less than 20 Angstroms, such as between 15-20 Angstroms and most preferably about Angstroms. The width ‘a’ of the spacers 28 in the I/O region 16 on the other hand remains greater than 20 Angstroms, such as between 20-25 Angstroms, and more preferably about 25 Angstroms.

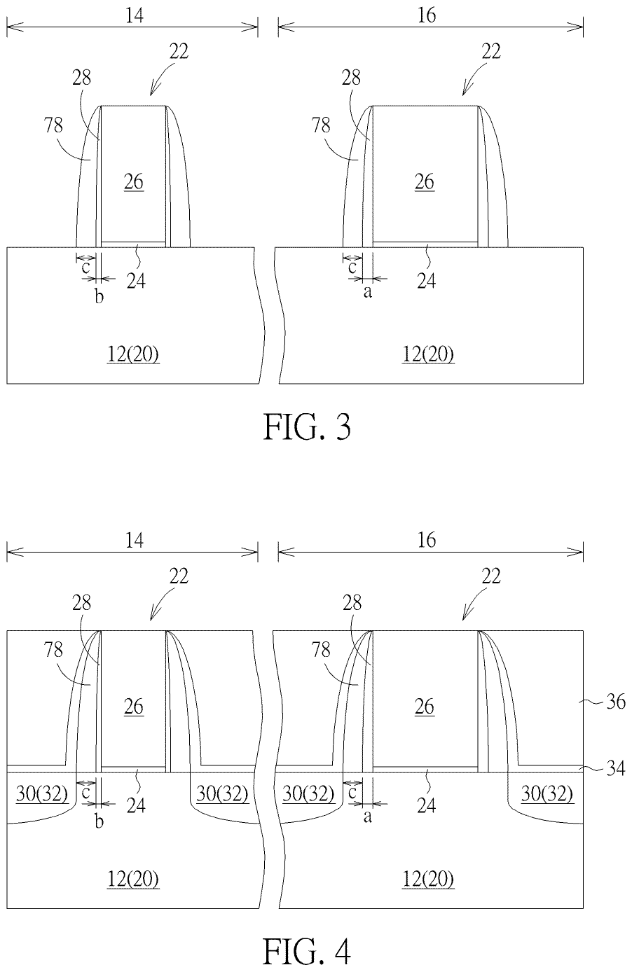

Next, as shown in FIG. 3, the patterned mask 74 is stripped, and another spacer 78 such as main spacer is formed adjacent to the spacer 28. At this stage, the spacers 78 formed in both the core region 14 and the I/O region 16 preferably have the same thickness or width. The width of each spacer 78 is preferably greater than 70 Angstroms, for example, ranging from 75-85 Angstroms, and most preferably about 80 Angstroms.

It is noteworthy that, at this stage, the gate structure 22 in each region includes a combination of spacers 28 and 78 having three distinct widths. Specifically, the inner spacers 28 in the core region 14 have the smallest width ‘b’, the inner spacers 28 in the I/O region 16 have an intermediate width ‘a’, and the outer spacers 78 formed in both the core region 14 and the I/O region 16 have the largest width ‘c’. Preferably, the width ‘c’ of the spacers 78 is greater than at least twice, and possibly three times, four times, five times or more than the width ‘a’ and/or width ‘b’ of the spacers 28. All such variations fall within the scope of the present invention. In addition, the spacers 78 formed at this stage may be composed of the same or different materials compared to the previously formed spacers 28. For example, the spacers 78 may include silicon oxide, silicon nitride, silicon carbide (SiC), silicon oxynitride (SiON), silicon carbonitride (SiCN), or combinations thereof, without being limited thereto.

Next, as shown in FIG. 4, a source/drain region 30 and/or an epitaxial layer 32 may then be formed in the fin-shaped structures 20 and/or the substrate 12 on both sides of the spacer 78. Optionally, a silicide (not shown) may be formed on the surface of the source/drain region 30 and/or the epitaxial layer 32. In the present embodiment, the source/drain region 30 and the epitaxial layer 32 may contain different dopants or materials depending on the type of the transistor being fabricated. For example, the source/drain region 30 may include p-type or n-type dopants, while the epitaxial layer 32 may include silicon-germanium (SiGe), silicon carbide (SiC), or silicon phosphide (SiP).

Next, a contact etch stop layer (CESL) 34 composed of silicon nitride could be selectively formed on the substrate 12 to cover the gate structures 22 and an interlayer dielectric (ILD) layer 36 is formed on the CESL 34. Next, a planarizing process, such as chemical mechanical polishing (CMP) process is conducted to remove part of the ILD layer 36 and part of the CESL 34 to expose the gate material layer 26 composed of polysilicon so that the top surfaces of the gate material layer 26, CESL 34, and ILD layer 36 in each of the core region 14 and I/O region 16 are coplanar.

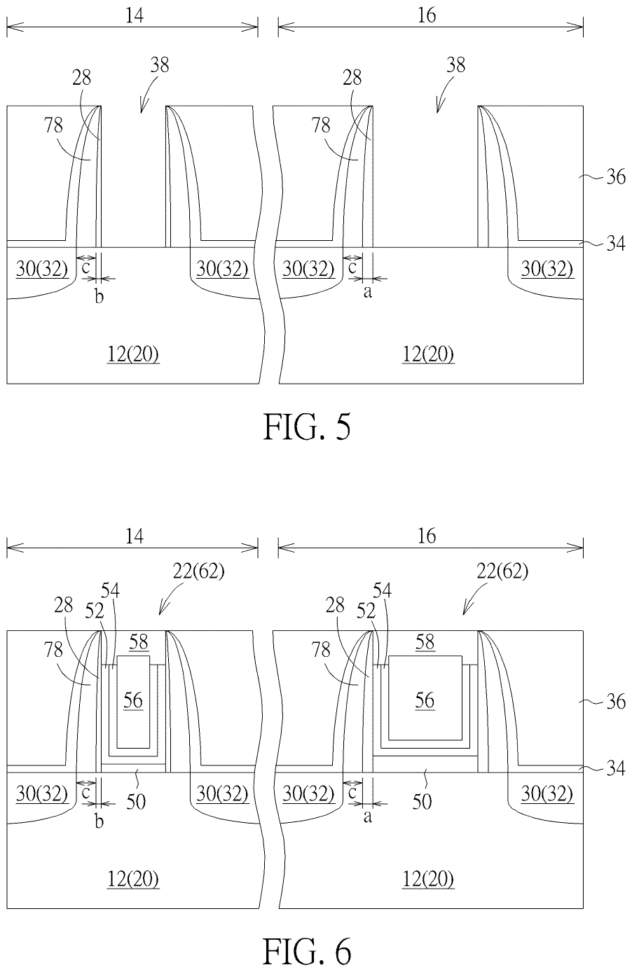

Next, as shown in FIG. 5, a replacement metal gate (RMG) process is conducted to transform the gate structures 22 into metal gates. For instance, a selective dry etching or wet etching process could be conducted by using etchant including ammonium hydroxide (NH₄OH) or tetramethylammonium hydroxide (TMAH) to remove the gate material layers 26 and gate dielectric layers 24 in the gate structures 22 in the core region 14 and I/O region 16 for forming recesses 38 in the ILD layer 36.

Next, as shown in FIG. 6, an oxide growth process such as a rapid thermal oxidation (RTO) process or an in-situ steam generation (ISSG) process is conducted to form a gate dielectric layer 50 made of silicon oxide in the recesses 38 in the core region 14 and I/O region 16. It should be noted that in order to accommodate the higher operating voltage of the I/O region 16, the thickness of the gate dielectric layer 50 in the I/O region 16 is preferably greater than that of the gate dielectric layer 50 in the core region 14

Next, a high-k dielectric layer 52, a work function metal layer 54, and a low resistance metal layer 56 are sequentially formed in the recess 38, and a planarizing process, such as CMP is conducted to remove part of the low resistance metal layer 56, part of the work function metal layer 54, and part of the high-k dielectric layer 52 for forming metal gates 62 or gate electrodes.

In this embodiment, the high-k dielectric layer 52 is preferably selected from dielectric materials having dielectric constant (k value) larger than 4. For instance, the high-k dielectric layer 52 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer 40 is selected from the group consisting of TiN and TaN, but not limited thereto.

In this embodiment, the work function metal layer 54 is formed for tuning the work function of the later formed metal gates to be appropriate in an NMOS or a PMOS. For an NMOS transistor, the work function metal layer 54 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 54 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 54 and the low resistance metal layer 56, in which the material of the barrier layer may include titanium (Ti), titanium nitride (TiN), tantalum (Ta) or tantalum nitride (TaN). Furthermore, the material of the low resistance metal layer 56 may include copper (Cu), aluminum (Al), titanium aluminum (TiAl), cobalt tungsten phosphide (CoWP) or any combination thereof.

Next, part of the high-k dielectric layer 52, part of the work function metal layer 54, and part of the low resistance metal layer 56 could be removed to form a recess (not shown), and a hard mask 58 could be formed in the recess so that the top surfaces of the hard mask 58 and ILD layer 36 are coplanar. The hard mask 58 could be selected from the group consisting of silicon oxide, silicon nitride, silicon oxynitride, and silicon carbon nitride. It should be noted that, during the etching process used to remove portions of the high-k dielectric layer 52, the work function metal layer 54, and the low resistance metal layer 56 to form the recess, the difference in etch selectivity among materials preferably results in the top surface of the low resistance metal layer 56 being slightly higher than the top surfaces of the high-k dielectric layer 52 and the work function metal layer 54.

Next, as shown in FIG. 7, a contact plug formation could be conducted to form contact plugs 64 electrically connecting the source/drain regions 30 on the core region 14 and I/O region 16 and then a stop layer 66 is formed on the ILD layer 36. In this embodiment, the formation of contact plugs 64 could be accomplished by removing part of the ILD layer 36 and part of the CESL 34 to form contact holes (not shown), and then depositing a barrier layer (not shown) and a metal layer into the contact holes. A planarizing process such as CMP is then conducted to remove part of the metal layer, part of the barrier layer, and even part of the ILD layer 36 to form contact plugs 64 in the contact holes as the top surface of the contact plugs 64 is even with the top surface of the ILD layer 36. In this embodiment, the barrier layer is selected from the group consisting of Ti, Ta, TiN, TaN, and WN, the metal layer is selected from the group consisting of Al, Ti, Ta, W, Nb, Mo, and Cu, and the stop layer 66 preferably includes oxides such as tetraethyl orthosilicate (TEOS). This completes the fabrication of a semiconductor device according to an embodiment of the present invention.

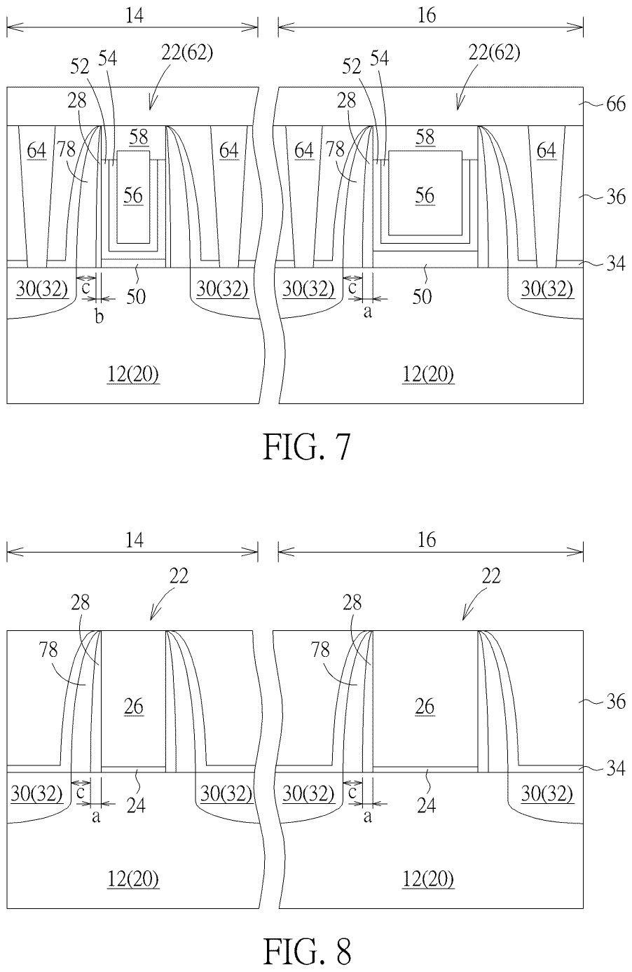

Referring to FIGS. 8-10, FIGS. 8-10 illustrate a method for fabricating a semiconductor device according to another embodiment of the present invention. As shown in FIG. 8, unlike the previously described embodiment in which a treatment process 72 is performed prior to the replacement metal gate (RMG) process or the formation of the recess 38 by removing a portion of the inner spacers 28 in the core region 14 to reduce their width, in other embodiments of the present invention, the etching step for thinning the inner spacers 28 may be omitted. Instead, outer spacers 78 could be directly formed adjacent to the inner spacers 28 without removing any portion of the inner spacers 28. Following this, the source/drain regions 30, the contact etch stop layer (CESL) 34, and the interlayer dielectric (ILD) layer 36 are sequentially formed. In other words, prior to forming the recess 38 by removing the gate material layer 26, only two types of spacer widths are present adjacent to the gate structures 22: the inner spacers 28 in both the core region 14 and the I/O region 16 have the same width ‘a’ and the outer spacers 78 in both regions have the same width ‘c’.

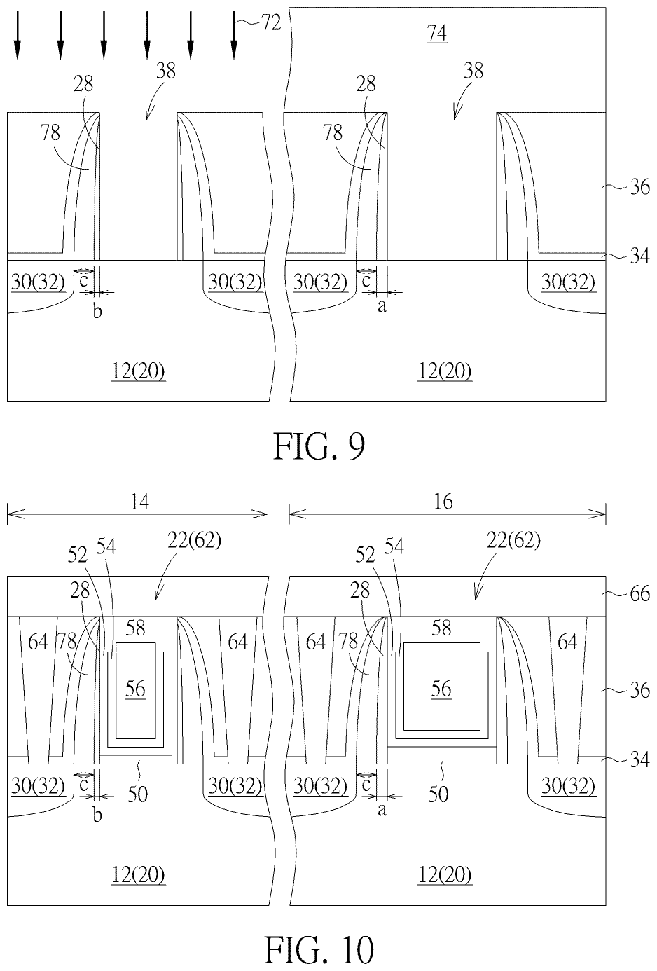

Next, as shown in FIG. 9, the gate material layer 26 and the gate dielectric layer 24 in the gate structures 22 of both the core region 14 and the I/O region 16 are first removed by etching to form recesses 38 within the ILD layer 36. A patterned mask 74 such as a patterned resist is then formed over the I/O region 16, and a treatment process 72 for example a wet etching or dry etching process is performed using the patterned mask 74 as an etch mask to partially remove the inner spacers 28 in the core region 14, thereby reducing the width ‘a’ of each spacer 28 to a narrower width ‘b’. From another perspective, although the spacer width in the core region 14 is reduced from width ‘a’ to width ‘b’ at this stage, similar to the reduction shown in FIG. 2, the difference lies in the direction of the spacer thinning. In the embodiment illustrated in FIG. 2, the reduction is achieved by thinning the outer sidewall of the spacer 28, whereas in the present embodiment, the reduction is achieved by thinning the inner sidewall of the spacer 28.

Subsequently, as shown in FIG. 10, the process may proceed similarly to that illustrated in FIGS. 6-7. A gate dielectric layer 50, a high-k dielectric layer 52, a work function metal layer 54, a low resistance metal layer 56, and a hard mask 58 are sequentially formed within the recesses 38 of both the core region 14 and the I/O region 16. Contact plugs 64 are then formed on both sides of the gate structures 22 to electrically connect to the source/drain regions 30. Finally, a stop layer 66 is formed over the ILD layer 36.

In general, when fabricating fin field-effect transistor (FinFET) devices in both the core region and the I/O region using a replacement metal gate (RMG) process, a thicker gate dielectric layer is typically formed in the I/O region to accommodate a higher operating voltage, such as approximately 3.3V. Since both the gate dielectric layer and the innermost spacers commonly contain oxygen-based materials such as silicon oxide, increasing the thickness of the gate dielectric layer in the I/O region can adversely impact the overall gate length (Lg) of the core region during the RMG process, particularly during the etching step that removes the polysilicon gate material to form the recess.

To resolve this issue, the present invention preferably employs an oxygen-free dielectric material such as silicon nitride (SiN) as the innermost spacer 28 adjacent to the gate electrode or gate structure. According to the embodiment shown in FIGS. 1-7, a treatment process 72 may be carried out before forming the recess 38 to partially remove the spacers 28 in the core region 14, thereby reducing their thickness or width. Alternatively, as illustrated in the embodiment of FIGS. 8-10, the treatment process 72 may be performed after the recess 38 is formed to similarly remove a portion of the spacers 28 in the core region 14. In either approach, the gate length of the core region can be adjusted accordingly. All such variations fall within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having a core region and an input/output (I/O) region;
forming a first gate structure in the core region and a second gate structure in the I/O region;
forming a first spacer adjacent to the first gate structure and a second spacer adjacent to the second gate structure, wherein the first spacer and the second spacer comprise different widths; and
forming a first source/drain region adjacent to the first spacer and a second source/drain region adjacent to the second spacer.

2. The method of claim 1, further comprising:
forming a third spacer adjacent to the first spacer and a fourth spacer adjacent to the second spacer;
forming an interlayer dielectric (ILD) layer around the third spacer and the fourth spacer;
removing the first gate structure and the second gate structure to form a first recess and a second recess; and
forming a first metal gate in the first recess and a second metal gate in the second recess.

3. The method of claim 2, further comprising performing a treatment process to remove part of the first spacer before forming the third spacer and the fourth spacer.

4. The method of claim 2, further comprising performing a treatment process to remove part of the first spacer after forming the first recess and the second recess.

5. The method of claim 2, wherein the third spacer and the fourth spacer comprise same width.

6. The method of claim 2, wherein a width of the first spacer is less than a width of the third spacer.

7. The method of claim 2, wherein a width of the second spacer is less than a width of the fourth spacer.

8. The method of claim 1, wherein a width of the first spacer is less than a width of the second spacer.

9. The method of claim 1, wherein the first spacer and the second spacer comprise non-oxygen compound.

10. A semiconductor device, comprising:
a substrate having a core region and an input/output (I/O) region;
a first gate structure in the core region and a second gate structure in the I/O region;
a first spacer adjacent to the first gate structure and a second spacer adjacent to the second gate structure, wherein the first spacer and the second spacer comprise different widths; and
a first source/drain region adjacent to the first spacer and a second source/drain region adjacent to the second spacer.

11. The semiconductor device of claim 10, further comprising:
a third spacer adjacent to the first spacer and a fourth spacer adjacent to the second spacer; and
an interlayer dielectric (ILD) layer around the third spacer and the fourth spacer.

12. The semiconductor device of claim 11, wherein the third spacer and the fourth spacer comprise same width.

13. The semiconductor device of claim 11, wherein a width of the first spacer is less than a width of the third spacer.

14. The semiconductor device of claim 11, wherein a width of the second spacer is less than a width of the fourth spacer.

15. The semiconductor device of claim 10, wherein a width of the first spacer is less than a width of the second spacer.

16. The semiconductor device of claim 10, wherein the first spacer and the second spacer comprise non-oxygen compound.

17. The semiconductor device of claim 10, wherein the first gate structure and the second gate structure comprise metal gates.
